(19) United States
(12) Patent Application Publication
(10) Pub. No.: US 2015/0366067 A1
(43) Pub. Date: Dec. 17, 2015

(54) Peripherally Mounted Components in Embedded Circuits

(71) Applicant: Edward Herbert, Canton, CT (US)

(72) Inventor: Edward Herbert, Canton, CT (US)

(21) Appl. No.: 14/717,829

(22) Filed: May 20, 2015

Related U.S. Application Data
(63) Continuation-in-part of application No. 62/000,960, filed on May 20, 2014.

(51) Int. Cl. H05K 1/18

(52) U.S. Cl. CPC H05K 1/183

(57) ABSTRACT

Semiconductor die and other components can be mounted in printed circuit boards with a binding agent at their periphery. This leaves both surfaces exposed for subsequent processing, usually over-plating with copper that is then etched to define a conductor pattern, just as in printed circuit manufacture. Methods using the surface tension of liquids for precise component placement in three dimensions (3-D) are shown. Optionally, micro-conductors can be used for the connections to the die, for reduced apparent resistance at high frequencies. The micro-channels between the micro-conductors can be a wick for liquid for evaporative cooling at the semiconductor surface as part of a heat pipe circuit.

### CROSS REFERENCE TO RELATED APPLICATIONS

This application is a Continuation in Part of a Preliminary Patent Application Ser. No. 62/000,960 entitled “Packaging for high speed semiconductor switches,” filed May 20, 2014. The Preliminary Patent Application is included herein by reference.

### BACKGROUND OF THE INVENTION

This invention relates to embedding components in printed circuit boards. This is becoming increasingly popular in electronic assembly, in particular, 3-D circuits. Embedded components usually are placed on a flat surface of a laminate, attached conventionally with solder balls or the like. Additional layers of laminate and resin are placed around the embedded component and above it, sometimes connecting other circuits to the embedded component with vias. Stress due to mismatched coefficients of thermal expansion is a problem, as is intermetallic interfaces if solder is used. Some newer components run at extreme temperatures, compounding the problems.

### SUMMARY OF THE INVENTION

This invention teaches that a die or other component can be mounted in a cavity in a printed circuit board using a binding agent at its periphery, leaving the top and bottom surfaces exposed for additional processing, typically over plating and etching using printed circuit techniques and materials to define interconnecting conductors.

Conceptually, the die can be located precisely within a cavity with a pick and place robot, and the peripheral binding agent can be placed using a precision glue extruder or 3-D printing. Practically, both are way too slow for high speed volume production, so this invention teaches various methods for precisely locating components relative to the printed circuit board using surface tension in a liquid. Precision placement in components by liquid surface tension is often used for micro-assembly, but this invention teaches how to apply it to precision placement in three dimensions (3-D).

One embodiment of the invention teaches how to terminate a semiconductor die or other component with flying leads with no plastic material. Such a device may be useful for high temperature applications.

One embodiment of the invention teaches using techniques of micro-machining to make printed-circuit connections having a large number of micro-conductors with micro-channels between them. The micro-conductors have reduced apparent resistance, similar to Litz wire, at high frequencies. They also can be an effective wick for liquid for evaporative cooling at the component surface as part of a heat pipe circuit.

### BRIEF DESCRIPTION OF THE FIGURES

FIGS. 1, 2 and 3 shows a perspective view, a top view and a section view, respectively, of a semiconductor die peripherally mounted in a die holder.

FIG. 4 shows that multiple dice can be peripherally mounted in an assembly.

FIG. 5 shows that after a die is peripherally mounted, copper can be deposited on both sides, then etched as in a printed wiring board to define electrical connections to the die.

In FIG. 6, a removable temporary carrier is used to locate the die precisely within the die holder at a desired vertical position as well as a desired lateral position.

FIGS. 7 A and 7B show a complex stacked assembly comprising, as an example, not a limitation, a capacitor with semiconductor switches on the top and the bottom. Each semiconductor switch is itself a stacked assembly, as an example, not a limitation, a GaN HEMT with a die on die MOSFET cascode switch, the MOSFET in turn having a die on die MOSFET driver.

FIGS. 8 and 9 show that a measured amount of bonding agent will flow by capillarity to distribute itself around a die or assembly located therein. The surfaces of the frame and the surfaces of the die or assembly should not be wet by the bonding agent.

FIGS. 10 and 11 show a perspective view and a partial section of a frame for receiving peripherally mounted dice.

FIGS. 12 and 13 show a perspective view and a partial section of a frame for receiving peripherally mounted dice. The periphery of each cavity has a bead of bonding agent applied as by dipping, as an example, not a limitation. The bonding agent wets the edges of the cavities, but does not wet the surfaces of the frame.

FIGS. 14, 15 and 16 show that if dice are dropped in general contact with the beads of bonding agent, with reference to FIGS. 12 and 13, they will settle into the correct location by surface tension.

FIG. 17 shows that the deposited conductors connecting a die to external circuits may be micro-machined to form micro-conductors, as a Litz wire analog. The micro-channels so formed may also be a wick as part of a heat pipe system.

FIG. 18 shows a prior art micro-machined part, a miniature inductor.

FIGS. 19 and 20 show that a die may be peripherally mounted in a soluble or meltable frame. Copper can be deposited on the surfaces, then etched to define conductors. Finally, the frame can be dissolved or melted to leave free flying leads.

FIG. 21 shows that the frame can contain pins. Connection to the pins is made my depositing copper, then etching it to the desired conductor pattern.

FIGS. 22 and 23 show that if a removable temporary holder for dice has wettable top surfaces that complement the shape of the dice, misalignment can be corrected by the surface tension.

FIG. 23 shows that a frame can be placed on the removable temporary holder and dice of FIG. 23, with the parts precisely located without fussy assembly.

FIGS. 25, 26 and 27 show that surface tension can precisely locate a die in a frame.

FIG. 28 shows that peripherally mounted parts can be assembled in a continuous strip.

### DETAILED DESCRIPTION

Embedding components in substrates is being increasingly for miniaturization, but a more important reason for some applications is reducing stray inductance. Usually, dice are mounted on a substrate surface, then additional layers and resin is added to surround it. Connections may be made under the die in the initial placement, particularly if the die is flipped, but sometimes micro-vias are made to the die from the top and/or bottom for electrical connection. Thermal expansion and material incompatibility can be problems.

By mounding dice by their peripheries in frames avoids some problems. Connections can be made to both surfaces, as both surfaces are exposed, using copper plating and etching as is done in printed circuit fabrication. If the peripheral bonding agent is compliant, it provides strain relief. The plated and etched copper connections may also be curved so that stress tends not to be transmitted to the die. If the die and the surface of the board are both copper initially, copper can be plated to them without introducing any dissimilar metals.

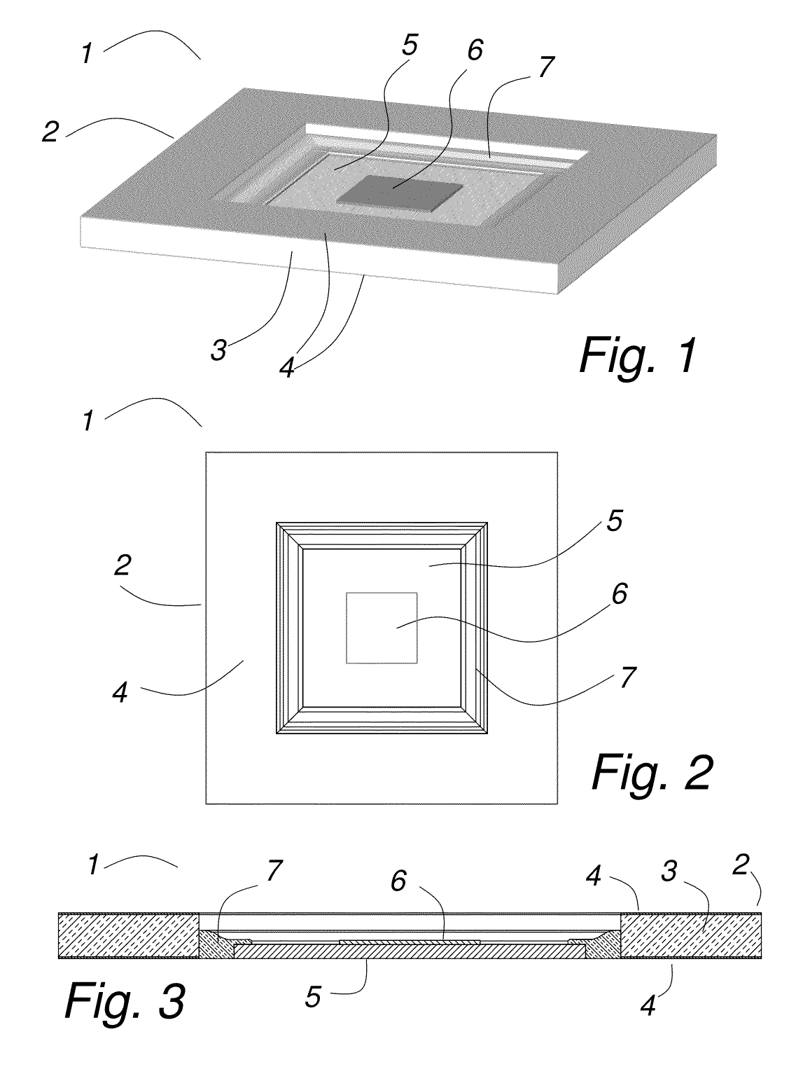

FIGS. 1, 2 and 3 show a perspective view, a top view and a section of a peripherally mounted assembly 1 having a frame 2. The frame 2 may comprise a substrate 3 with copper laminate 4, 4 on both surfaces, as an example, not a limitation. As an example, not a limitation, a die-on-die assembly is shown comprising a first die 5 with a second die 6 mounted on it. As an example, not a limitation, this could be a GaN HEMT with a cascode connected vertical MOSFET mounted on it, with the source of the MOSFET making direct connection to a central gate pad of the GaN HEMT.

The first die 5 is placed in its correct location within the frame 2 and a peripheral bonding agent 6 is applied around the die 5, bonding it to the frame 2. Conceptually, the frame 2 and the die 5 may be fixtured, or they may be precisely located on a vacuum table or perhaps on a removable temporary sticky surface, as examples, not limitations. Conceptually, the bonding agent 7 may be dispensed with a precision glue dispenser or 3-D printing and cured, preferably by UV flash curing.

FIG. 3 shows that the peripherally mounted assembly 1 has a flat surface, which may be desirable if the assembly is to be mounted on a heat sink or other flat surface.

Neither precision placement of the die 5 by pick-and-place equipment nor precision extrusion of the bonding agent 7 by a precision glue dispenser or 3-D printer are fast operations, relatively, so alternatives are explored for this invention.

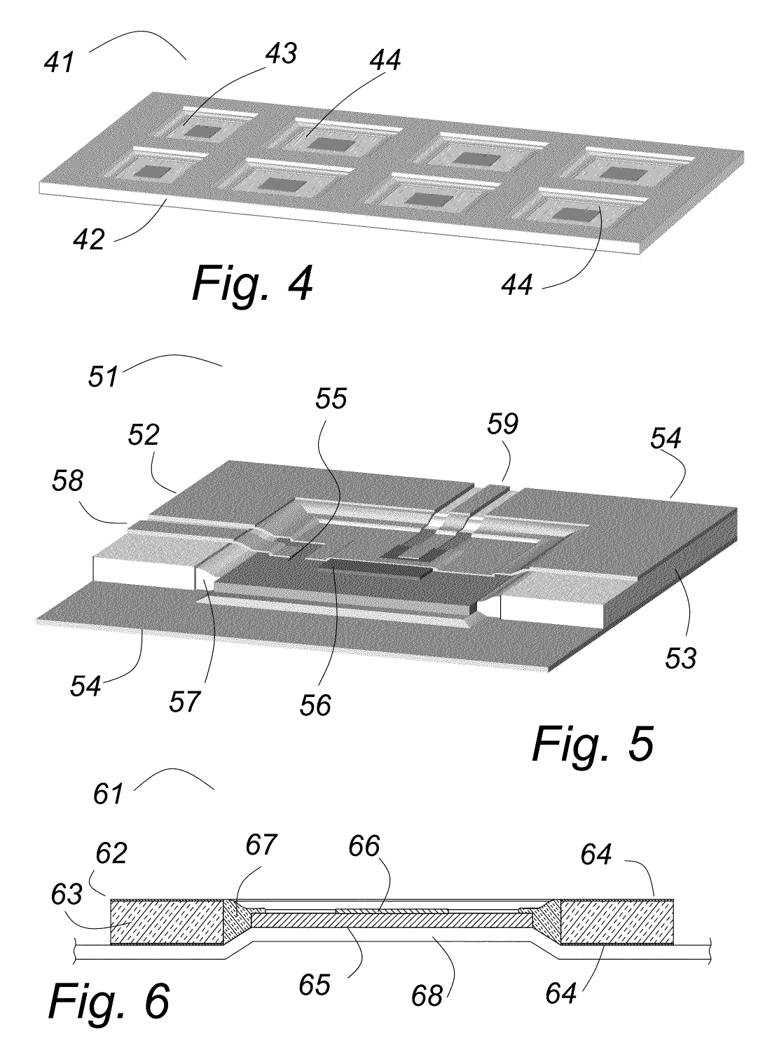

FIG. 4 shows that multiple die 44-44 can be mounted in a frame 42 using a peripheral bonding agent 43 to make an electronic assembly 41.

FIG. 5 shows a peripherally mounted assembly 51 comprising a first die 55 with a second die 56 mounted on the first die 55. A frame 52 may comprise a substrate 53 with copper laminate 54, 54 on its top and bottom surfaces. A peripheral bonding agent 57 locates the first die 55 within the frame 52. In distinction to the peripherally mounted assembly 1 of FIGS. 1, 2 and 3, the first die 55 is raised with respect to the bottom surface of the frame 52. In FIG. 5, etched copper connections 58 and 59 are shown connected to the first die 55 and the second die 56, as examples, not limitations. It is implied that an intermediate step comprised “seeding” the entire surface of the peripherally mounted assembly 51 so that it can be copper plated, then copper is plated over the entire surface to the desired thickness. Both the seeding step and the copper plating step are routing operations used by the printed circuit industry, and anyone skilled in the art of printed circuits will be able to apply them for this invention without undue experimentation. Seeding usually involves the electroless deposition of a very thin metallic coating with sufficient conductivity that electrolytic plating of copper can be initiated on otherwise non-conductive surfaces, such as the binding agent 57 and any other non-conductive surfaces.

As with any printed circuit assembly, multiple layers of copper with insulation between them and vias to interconnect them can be used for more complex connections, as would be understood by one skilled in multi-layer printed circuit board design and manufacture.

FIG. 6 shows a peripherally mounted assembly 61 having a frame 62 that may comprise a substrate 63 with top and/or bottom copper laminate 64, 64. A first die 65 has a second die 66 mounted on it, as an example, not a limitation. A bonding agent 67 makes a peripheral seal holding the first die 65 in its correct location within the frame 62.

A removable temporary fixturing surface 68 has raised bumps that are complementary to the cavity in the frame 62, so the frame 62 can be located precisely on it. If the frame 62 is introduced to the removable temporary fixturing surface 68 with positioning that is approximately correct, it will self-align precisely as it is pressed down. If the first die 65 was located precisely on the top of the bumps in the removable temporary fixturing surface 68, then the entire peripherally mounted assembly 61 is precisely located. It is contemplated that the removable temporary mounting surface 68 is removed once the bonding agent 67 is in place and cured.

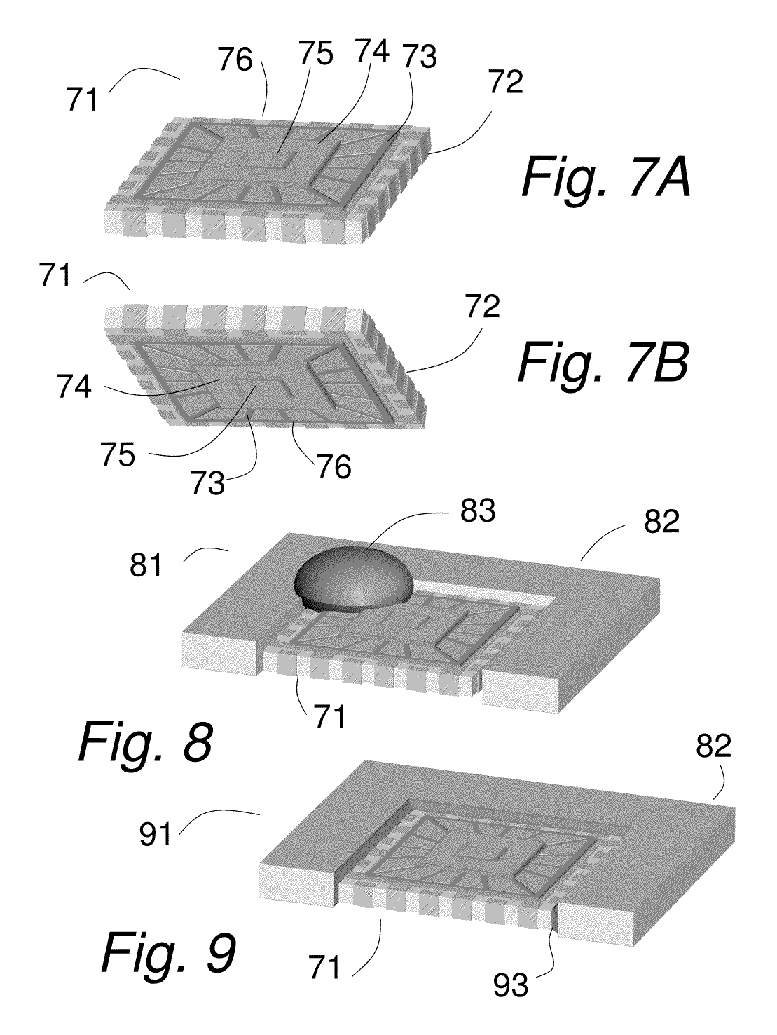

FIGS. 7A and 7B show, respectively, top and bottom surfaces of an electronic assembly stack 71. As an example, not a limitation, the electronic assembly stack may comprise a decoupling capacitor 72 with semiconductor switches 73, 73 on its top and bottom surfaces, respectively. In this example, the semiconductor switches 73, 73 are similar cascode switches with driver circuits, and may, as an example, not a limitation, comprise a GaN HEMT 76 with a cascode MOSFET 75 which may in turn have a die-on-die driver 75. This is a representative switch for a buck converter and other power converter circuits, and assembling them in as stack in this manner minimizes the stray conductance between the respective components, which is critical for high frequency operation. Note, though, that the “wedding cake” like stack-up would make it very difficult to embed this electronic assembly stack in a conventional embedded 3-D package.

FIGS. 8 and 9 show sections of a partially completed peripherally mounted assembly 81 and the final peripherally mounted assembly 91, in which the electronic assembly stack 71 of FIGS. 7A and 7B, as an example, not a limitation are mounted in a frame 82. FIG. 8 shows that a measured glob of bonding agent 83 can be placed anywhere on the space between the electronic assembly stack 71 and the frame 82, and it will spread by capillarity as shown in FIG. 9 to become a peripheral bonding agent 93. The assembly 91 can then be plated with copper on both sides, then the copper can be etched to define the circuit connections.

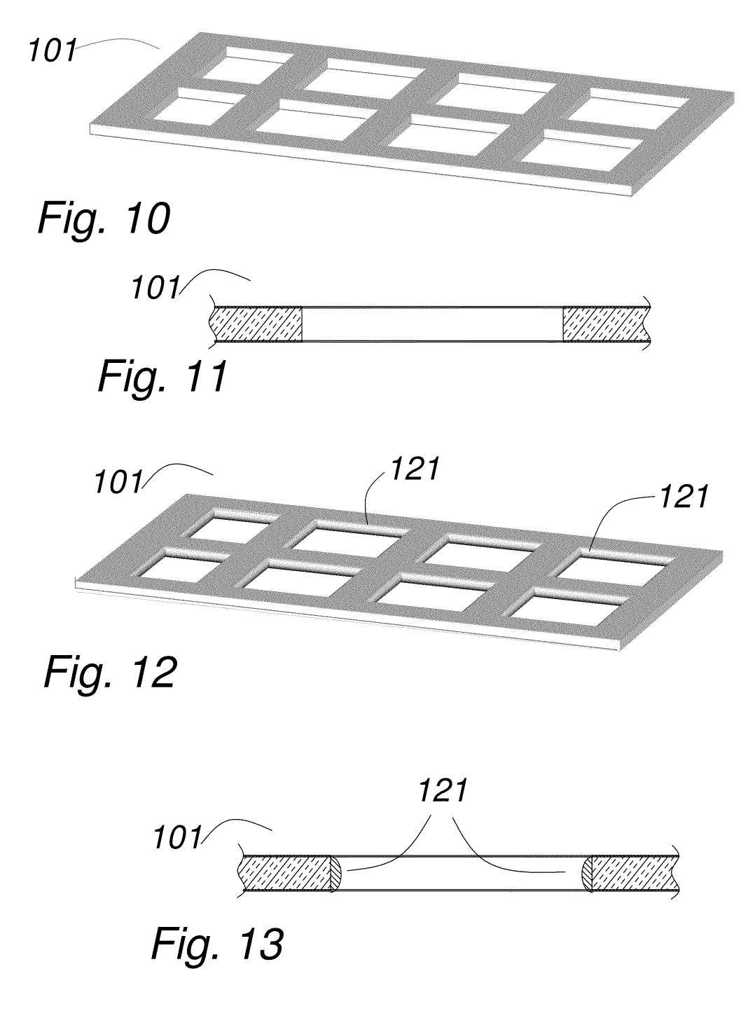

FIGS. 10 and 11 show, respectively, a perspective view and a partial section of a circuit board assembly 101. The circuit board assembly 101 (or frame) may be simply a substrate with copper on its top and/or bottom surface, but for a multiple dice assembly, it is contemplated that it may be a more complex assembly, perhaps comprising a multi-layered printed circuit assembly, and perhaps it may contain other embedded components. Circuit terminations are brought to the top or bottom surface for subsequent connection to the dice and external circuits. This would be well known by those skilled in the art of electronic assembly, particularly printed circuit assembly, and it is not a point of novelty of this invention, so it is only mentioned briefly.

FIGS. 12 and 13 show that the peripheries of cavities in the circuit board assembly 101 can be coated with a bonding agent 121, 121. If the bonding agent 121, 121 does not wet the surfaces of the circuit board assembly 101, but if it does wet the peripheries of the cavities, then a rounded meniscus will form around the peripheries of the cavities.

The shape of the meniscus will be determined by the properties of the bonding agent 121, but it may be desirable to use an air-knife or other means to refine the meniscus formation and prevent bubble webs forming across the cavities. It is contemplated that the bonding agent is a liquid and remains a liquid for subsequent processing. However, a viable alternative is to let the bonding agent solidify. This may be desirable if it is to be stored before use, and if so, the bonding agent could be thermosetting so that it can subsequently be melted for further assembly.

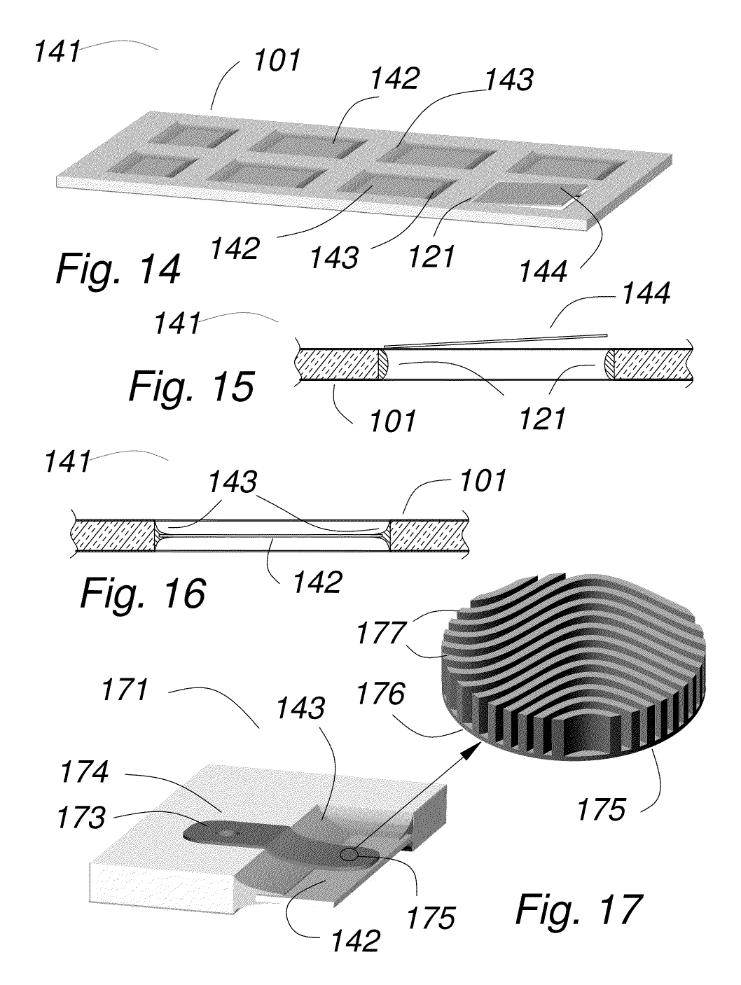

FIGS. 14, 15 and 16 show, respectively, a perspective view and partial sectional views of an electronic assembly 141, the partial sectional view of FIG. 15 showing an intermediate assembly step and the partial sectional view of FIG. 16 showing the final assembly. The electronic assembly 141 comprises the circuit board 101 of FIGS. 10 and 11 with the bonding agent 121 of FIGS. 12 and 13 already in place. Several dice 142, 142 are in place, but one die 144 is being placed. As shown more clearly in the partial sectional view of FIG. 15, the die 144 is above the circuit board 101, and the bonding agent 121 still is undisturbed.

As the die 144 makes contact with the bonding agent 121, its periphery is wetted and it is drawn into position by surface tension as shown in FIG. 16. In its final shape, the bonding agent 121 of FIGS. 12, 13, 14 and 15 becomes the bonding agent 143 of FIGS. 14 and 16. When in place, the die 144 of FIGS. 14 and 15 becomes the die 142 of FIGS. 14 and 16. The surface tension of the bonding agent 143 tends to hold the die 142 in position both laterally and vertically, though gravity may influence its final position somewhat. It is contemplated that once the die 142 is in place, the bonding agent 143 will be cured. UV flash cure is preferred for its speed.

UV flash cure also introduces the possibility of high speed computerized visual inspection. The UF flash can be suppressed if any dice are misaligned or otherwise compromised to facilitate repair.

FIG. 17 shows a section of a circuit board assembly 171 comprising a circuit board 174 with a die 142 peripherally mounted by a bonding agent 143. One printed conductor 173 is shown making a connection from the circuit board assembly 171 to the die 142. Several features are noteworthy. One is that the printed conductor 173 has a curved contour as it leaves the die 142 and connects to the printed circuit assembly 171. This curved contour will not transmit significant stress to the die 142. If the circuit board assembly 171 initially had a bonded copper laminate top surface, and if the die 142 initially had a copper pad, then the connection made by copper plating has no discontinuities or intermetallic interconnections. For ordinary, non-critical applications, the printed conductor 173 may be an ordinary printed circuit conductor, defined by plating and etching.

The inset 175 shows, however, that the surface of the printed conductor may be fabricated using micro-machining techniques to comprise a large number of micro-conductors 177.

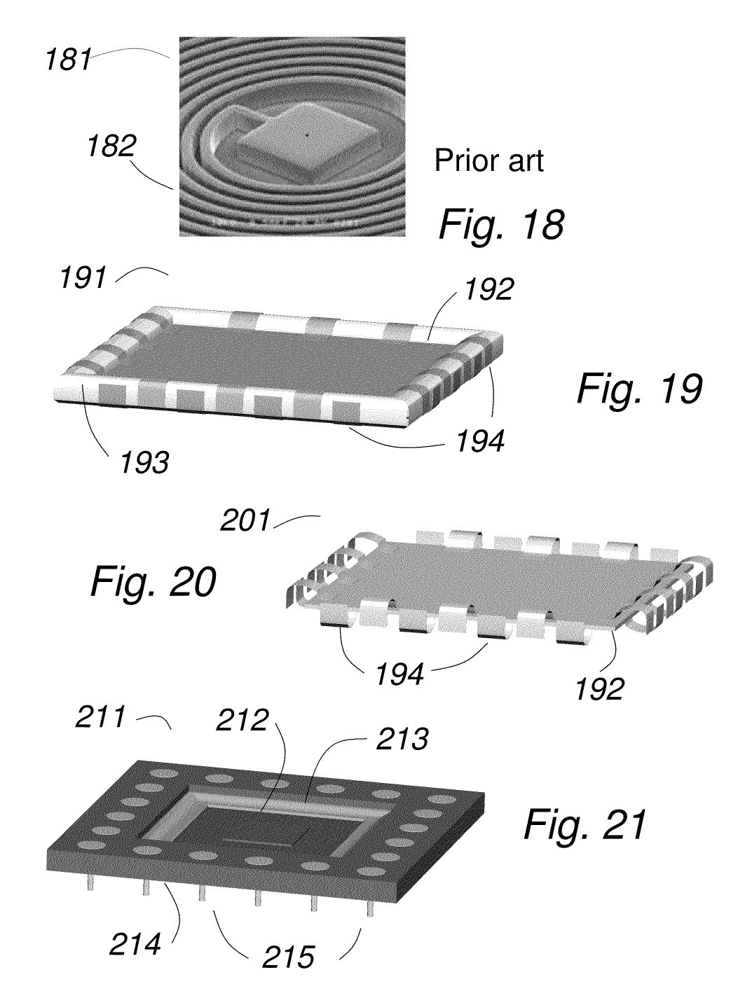

FIG. 18 shows a prior art miniature inductor 182 comprising a high aspect ratio conductor 182, to further the discussion. In making micro-machined structures, a thin copper plating is coated with a relatively thick photo resist. The photo resist is then exposed, perhaps with a laser, to define a very fine conductor pattern. The photo resist is then developed and washed away from where the conductors are to be formed to make a channel in the photo resist. The whole is then copper plated, and the copper plate builds up in the channels. Conductors on the order of 20 μm thick with comparable spacing can be formed, with a height of 100 μm or more. Because the initial copper base is continuous underneath the resist, the resist then has to be dissolved and washed away, so that the residual copper can be etched away to separate the conductors and define the inductor coils 182 of FIG. 18, as an example.

Returning to the section 175 of FIG. 17, there are some noteworthy differences. For one, the underlying copper plating 176 is relatively thick and is not removed. It should be very thin, nonetheless, so that its penetration depth is not an impediment to current flow at the frequency of interest. For a fast-switching power converter, that may be a very high frequency. After all, it is the Fourier component of the rising and falling edges of the waveform that are critical to fast switching.

The individual micro-conductors 177-177 should be thin and have a high aspect ratio. If this is done, the micro-conductors are thin relative to the penetration depth at the frequency of interest, and have some of the advantages of Litz wire. Micro-machining is a fussy operation and is not tolerant of misalignment, inclusions or gaps. The contemplated micro-conductors 177-177 of the printed wiring connection 173 are not nearly as critical, so less exacting manufacturing procedures should suffice, which may be much more economical. For one, while the pattern should be reasonably well defined, its location is not particularly critical. A few inclusions (shorts) would not matter, nor would gaps (opens) as the underlying copper would maintain and restore conduction across the gap.

Note that the micro-conductors 177-177 are shown as being wavy. This optional feature is contemplated to transfer less stress to the die 142 due to mismatches of the respective coefficients of thermal expansion, an important factor with large die or when the temperature varies frequently or a lot.

For considerations of improved apparent resistance at high frequency alone, the photo resist need not be removed, and it may be preferred in some applications to leave it in place. However, if it is removed, the plurality of closely spaced, deep micro-channels can serve as a wick for coolant in a heat pipe circuit, allowing evaporative cooling right at the surface of the die 142. If a similar pattern is used on the reverse side of the die 142, evaporative cooling from both surfaces is practical.

Practically, it may be much easier to make the micro-machined fine micro-conductor pattern on the semiconductor at the wafer or die level of manufacturing. While not optimum, having the micro-conductor pattern only on the die would be a significant improvement. To prevent obscuring it, the fine micro-conductor pattern may be mostly covered with resist, leaving a margin exposed at the edge, and subsequent plating to connect the die to the rest of the circuitry can be conventional plating from the margin.

FIG. 19 shows a peripherally mounted assembly 191 in which a die 192 is mounted in a frame 193. Subsequent plating and etching defines leads 194-194. FIG. 20 shows that the frame 193 has been dissolved or melted, leaving a plastic-free package 201 with flying leads. Some newer semiconductor materials can operate at extremely high temperatures, high enough to challenge conventional packaging methods and materials.

Variants may include using a two-part frame in place of the frame 193 so that part of it can be dissolved and part remains to protect and reinforce the die 192. The advantages of flying leads 194-194 is preserved while better protecting the die 192.

This method can be applied to die mounted in electronic assemblies as well. With reference to FIG. 17, consider that the binding agent 143 may be soluble or meltable and is removed after the printed wiring connection 173 has been made. The die 142 would be supported by the printed wiring connection 173, presumably one of a plurality of similar printed wiring connections around the die 142. The circuit board 143 could be ceramic, resulting in an assembly that was free of plastic. The die 142 would be well supported, but with resilient printed wiring connections with sufficient freedom of motion to absorb any stress due to differences in the coefficients of thermal expansion of the materials. Further, the continuity of the copper conductors, with no transitions between materials, would avoid many problems of rigid intermetallic connections.

FIG. 21 shows a peripherally mounted assembly 211 having a die 212 mounted in a frame 214 with a binding agent 213. The frame further has a plurality of pins 215-215 that protrude from the bottom surface and that have flush contact pads on the top of the frame 214 to which plated connections may be made. Obviously, this is but one example of a wide variety of contacts that could be attached to, molded within or otherwise be part of a frame that is peripherally attached to a die.

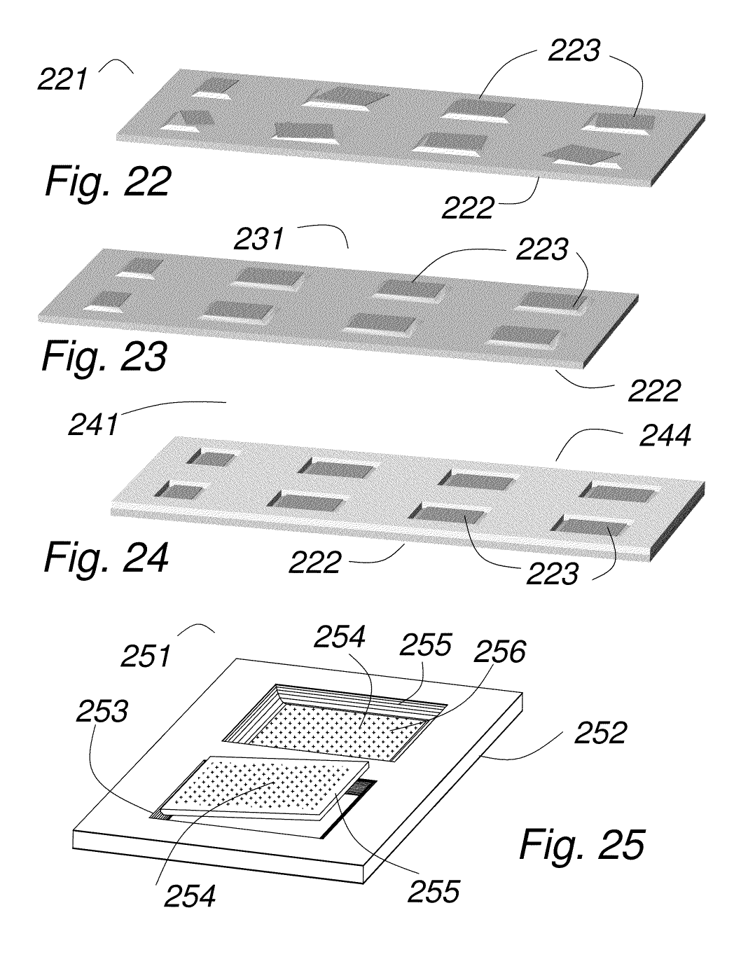

FIG. 22 relates to FIG. 6, and shows a method of manufacturing similar assemblies in more detail. A removable temporary assembly 221 comprises a removable temporary carrier 222 with a plurality of dice 223-223 placed upon it in a haphazard manner, as might occur with very high speed die handling machines that lack the precision of conventional but slow pick and place robots. The removable temporary carrier 222 can be wetted by a fluid that cannot be seen, and so can be the plurality of dice 223-223. FIG. 23 shows the same assembly, now designated as a removable temporary assembly 231, the difference being that the plurality of dice 223-223 have been pulled into alignment with a plurality of flat bumps on the removable temporary carrier 222 by surface tension. Using surface tension of wetting fluids is a well-known method of locating parts with precision in micro-assembly.

FIG. 24 shows that a circuit board 244 can then be placed on the removable temporary carrier 223 to make an intermediate assembly 241. The circuit board 244 may also wetted by the fluid, and the fluid may or may not be allowed to harden as a trade-off of the method of assembly. The fluid may cool and harden, if it is a material such as wax, or it could be flash cured with UV The plurality of dice 223-223 are now precisely located within the circuit board 224 without the need for precision placement by machine.

Alternatively, using a pattern of wettable areas and non-wettable areas, a flat removable temporary carrier can take advantage of the same accurate positioning by surface tension, locating both the individual dice and the circuit boards if the surfaces are wettable and conform to complementary wettable and non-wettable patterns on the removable temporary carrier. This may be useful to make the peripheral mounted assembly 1 of FIGS. 1, 2 and 3 having a flat bottom surface.

With reference to FIG. 6, the binding agent 67 can now be added. Preferably, the surface of the printed circuit 244 has a non-wettable surface, and so do the top surfaces of the plurality of dice 223-223. The binding agent can be placed as in FIG. 8, to spread by capillarity. Alternatively, the removable temporary assembly 241 can be dipped in liquid binding agent, which will wet only the edges of the cavities there in and the edges of the plurality of dice 223-223 to make the peripheral binding agent 67 of FIG. 6 for each of the plurality of dice 223-223. Finally, the removable temporary carrier can be removed leaving a circuit board with peripherally mounted dice for subsequent plating and etching to define the connections.

FIGS. 25, 26 and 27 continues the discussion of FIGS. 14, 15 and 16, with more detail. FIG. 25 shows an assembly 251 comprising a circuit board 252 with two cavities. Two dice are installed therein, a first die 255 is being installed, and a second die 256 is in place. Within the circuit board 252 at the location for the second die 256, a binding agent 253 has wetted the periphery of the cavity in the circuit board 252 and has a generally rounded surface determined by surface tension. The top and bottom of the surface board are not wetted by the binding agent 253. If this is not the nature of the materials on the top and bottom surfaces of the circuit board 252, they must be treated with a non-wetting agent such as wax, as an example, not a limitation.

The top and bottom surfaces of the dice 255 and 256 are selectively non-wettable in the areas 254-254 shown by hatching in FIG. 25. As a generality, the margins of the dice 255 and 256 are wettable by the binding agent 253, and the rest of the surfaces of the dice 255 and 266 are not wettable.

The first die 256 is in place within the cavity in the circuit board 222. The binding agent 255 has wetted the margin of the first die 256 and has formed a curved meniscus bridging the first die 256 and the peripheral surface of the cavity within the circuit board 252.

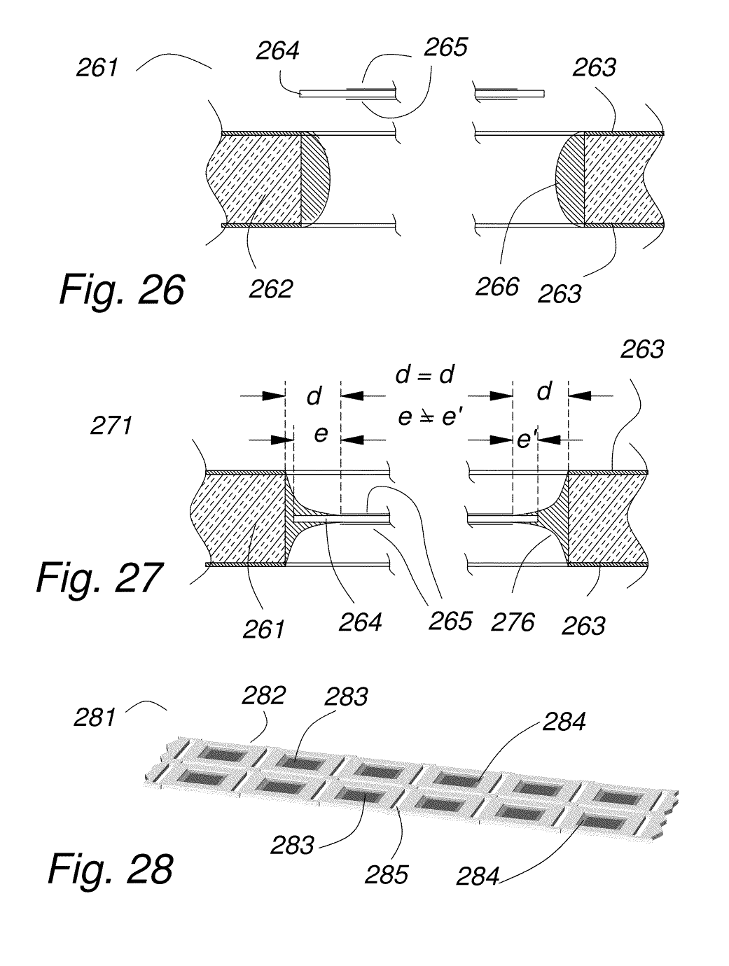

FIG. 26 examines this in more detail with a partial cross section 261 showing in larger detail a die 264 and a circuit board 262. The circuit board 262 may have top and bottom surfaces of copper cladding 263, 263. Regardless, the top and bottom surface of the circuit board are not wettable by a binding agent 266, whether they are naturally non-wettable or treated to be so. The surfaces of the die 264 are also treated to be non-wettable in the areas designated by lines 265, 265. In general, the margins of the die 264 are wettable, but the rest of the surfaces are not.

FIG. 27 shows an assembly 271 that is the assembly 261 of FIG. 26 except that the die 264 is in place. The binding agent 266 has wet the margins of the die 264 and has taken a new shape 276 with a meniscus determined by surface tension. The importance of FIG. 27 is that it shows that surface tension exerts force on the die 264 such that the area of the meniscus is minimized, though there may be minimal influences of other forces such as gravity. In particular, the surface between the edges of the non-wettable areas 265, 265 and the edges of the cavity in the circuit board 261 are equal on both sides, the dimensions designated as d, d. As long as the edge of the die 264 does not reach to the edge of the cavity in the circuit board, it has no significant influence on the position of the die 264, as the tension on the wettable areas are balanced. The margin e on one side of the die 264 may not be equal to the margin e′ on the other side of the die 264. In this manner, if the registration of the non-wettable areas 265, 265 on the die have good alignment with the die metallization, the alignment of the die metallization to the circuit board will have good precision even if the edges of the die 264 are irregular or misaligned to the metallization of the die 264.

Because the surface area of the meniscus of the binding agent 276 is minimized by surface tension, the vertical position of the die 264 will be centralized in the printed circuit board 261, though there may be some minimal influence of gravity and other forces.

FIG. 28 shows that it is contemplated that peripherally mounted dice 283-283 may be assembled in frames 282-282 as a continuous strip 281. There may be slots 285 between adjacent frames 282-282 so that subsequently plated conductors can be on the outer vertical surfaces of the frames 282-282 as well as on the top and bottom surfaces. Peripheral binding agents 284-284 can be applied using any of the methods disclosed in this specification and others as well, but it is contemplated that that the continuous strip may be coated as in FIGS. 15 and 26 by passing through a tank of liquid binding agent, and that the die 283-283 may be placed with precise alignment as in FIGS. 115, 16 and 27 with subsequent flash cure by UV.

1. A printed circuit assembly with at least a first peripherally mounted component comprising
a printed circuit board having therein at least a first cavity for receiving at least a first component
the at least a first cavity extending from a top surface to a bottom surface of the printed circuit board and having exposed peripheral edges,
the at least a first component being located within the at least a first cavity with a clearance gap between the exposed peripheral edges of the at least a first cavity and the at least a first component
the at least a first component being retained in place within the printed circuit board by a binding agent that fills the clearance gap between the exposed peripheral edges of the at least a first cavity and the at least a first component.

2. The printed circuit assembly of claim 1 wherein
the printed circuit assembly further comprises copper plating plated onto at least one of the top surface and the bottom surface of the printed circuit board, the binding agent and the at least a first component,
the copper plating further being selectively etched to define at least a first copper conductor from the at least a first component and the printed circuit board.

3. The printed circuit assembly of claim 2 wherein
the binding agent is soluble.

4. The printed circuit assembly of claim 2 wherein the printed circuit board is soluble.

5. The printed circuit assembly of claim 1 wherein the printed circuit board further comprises a plurality of terminals.

6. The printed circuit assembly of claim 1 wherein
the binding agent is applied as a liquid,
the binding agent fills the clearance gap by capillarity, and
the binding agent is cured to become a solid.

7. The printed circuit assembly of claim 1 wherein
the top surface and the bottom surface of the printed circuit board are not wettable,
the exposed peripheral edges of the at least a first cavity in the printed circuit board are wettable,
the binding agent is applied as a liquid and forms a meniscus on the exposed peripheral edges of the at least a first cavity in the printed circuit board,
the at least a first component has a wettable margin area at its edges
the at least a first component is placed on the meniscus of the binding agent,
the at least a first component is drawn into the binding agent and positioned therein by surface tension, and
the binding agent is cured to become a solid.

8. The printed circuit assembly of claim 6 further comprising
a removable temporary carrier to hold the at least a first component precisely located with respect to the printed circuit board during assembly.

9. The printed circuit assembly of claim 8 wherein
the at least a first component is precisely located with respect to the removable temporary carrier using
the surface tension of a liquid and
complementary patterns of wettable areas on the at least a first component and on the removable temporary carrier.

10. The printed circuit assembly of claim 8 wherein
the printed circuit board is precisely located with respect to the removable temporary carrier using at least a first protrusion on the removable temporary carrier that is complementary to the at least a first cavity in the printed circuit board

11. The printed circuit assembly of claim 8 wherein
the printed circuit board is precisely located with respect to the removable temporary carrier using
the surface tension of a liquid and
complementary patterns of wettable areas on the printed circuit board and on the removable temporary carrier.

12. The printed circuit assembly of claim 2 wherein
at least a first portion of the at least a first copper conductor comprises micro-conductors with micro-channels between the micro-conductors so as to have a lower apparent resistance to high frequency ac current.

13. A printed circuit assembly with at least a first peripherally mounted component comprising
a printed circuit board having therein at least a first cavity for receiving at least a first component
the at least a first cavity extending from a top surface to a bottom surface of the printed circuit board and having exposed peripheral edges,
the top surface and the bottom surface of the printed circuit board are not wettable,
the exposed peripheral edges of the at least a first cavity in the printed circuit board are wettable,
a binding agent that is applied as a liquid and forms a meniscus on the exposed peripheral edges of the at least a first cavity in the printed circuit board,
the at least a first component has a wettable margin area at its edges
the at least a first component is placed on the meniscus of the binding agent,
the at least a first component is drawn into the binding agent and positioned therein by surface tension, and
the binding agent is cured to become a solid.

14. The printed circuit assembly of claim 13 wherein
the printed circuit assembly further comprises copper plating plated onto at least one of the top surface and the bottom surface of the printed circuit board, the binding agent and the at least a first component,
the copper plating further being selectively etched to define at least a first copper conductor from the at least a first component and the printed circuit board.

15. The printed circuit assembly of claim 14 wherein
the binding agent is soluble.

16. The printed circuit assembly of claim 14 wherein
the printed circuit board is soluble.

17. The printed circuit assembly of claim 14 wherein
at least a first portion of the at least a first copper conductor comprises micro-conductors with micro-channels between the micro-conductors so as to have a lower apparent resistance to high frequency ac current.

18. A printed circuit assembly with at least a first peripherally mounted component comprising
a printed circuit board having therein at least a first cavity for receiving at least a first component
the at least a first cavity extending from a top surface to a bottom surface of the printed circuit board and having exposed peripheral edges,
the at least a first component being located within the at least a first cavity with a clearance gap between the exposed peripheral edges of the at least a first cavity and the at least a first component,
the exposed peripheral edges of the at least a first cavity in the printed circuit board are wettable,
the at least a first component has a wettable margin area at its edges,
a removable temporary carrier to hold the at least a first component precisely located with respect to the printed circuit board during assembly,
a binding agent that is applied as a liquid,
the binding agent fills the clearance gap by capillarity, and
the binding agent is cured to become a solid.

19. The printed circuit assembly of claim 18 wherein
the printed circuit board is precisely located with respect to the removable temporary carrier using at least a first protrusions on the removable temporary carrier that is complementary to the at least a first cavity in the printed circuit board.

20. The printed circuit assembly of claim 18 wherein
the printed circuit board is precisely located with respect to the removable temporary carrier using
the surface tension of a liquid and
complementary patterns of wettable areas on the printed circuit board and on the removable temporary carrier.

21. The printed circuit assembly of claim 18 wherein
the printed circuit assembly further comprises copper plating plated onto at least one of the top surface and the bottom surface of the printed circuit board,
the copper plating further being selectively etched to define at least a first copper conductor from the at least a first component and the printed circuit board.

22. The printed circuit assembly of claim 18 wherein the binding agent is soluble.

23. The printed circuit assembly of claim 18 wherein
the printed circuit board is soluble.

24. The printed circuit assembly of claim 21 wherein
at least a first portion of the at least a first copper conductor comprises micro-conductors with micro-channels between the micro-conductors so as to have a lower apparent resistance to high frequency ac current.
